(19) United States
(12) Patent Application Publication
(10) Pub. No.: US 2018/0211836 A1
(43) Pub. Date: Jul. 26, 2018

(54) TEMPLATE FORMATION FOR FULLY RELAXED SIGE GROWTH

(71) Applicant: Applied Materials, Inc., Santa Clara, CA (US)

(72) Inventors: Chun YAN, San Jose, CA (US); Xinyu BAO, Fremont, CA (US); Yi-Chiau HUANG, Fremont, CA (US); Hua CHUNG, San Jose, CA (US); Schubert S. CHU, San Francisco, CA (US)

(21) Appl. No.: 15/652,736

(22) Filed: Jul. 18, 2017

Related U.S. Application Data
(60) Provisional application No. 62/448,563, filed on Jan. 20, 2017.

(51) Int. Cl. H01L 21/02; H01L 21/306; H01L 21/308; H01L 21/027; H01L 29/161; H01L 29/06; H01L 29/10

(52) U.S. Cl. CPC H01L 21/02532; H01L 21/02381; H01L 21/02164; H01L 21/02488; H01L 21/30604; H01L 29/1054; H01L 21/0273; H01L 21/02057; H01L 29/161; H01L 29/0649; H01L 29/0657; H01L 21/3085

(57) ABSTRACT

The present disclosure generally relates to a device having a thin, low-defect, fully-relaxed silicon germanium (SiGe) layer, and methods of manufacture thereof. The methods generally include depositing a silicon oxide layer on a silicon layer, patterning the silicon oxide layer, exposing the silicon oxide layer to an etchant to form one or more recesses in the silicon layer and one or more faceted silicon oxide caps, and epitaxially growing a silicon germanium layer in the one or more recesses and over an apex of the one or more faceted silicon oxide caps. The device generally includes a silicon layer having one or more recesses defining one or more vertical extensions, one or more faceted silicon oxide caps on the one or more vertical extensions, and a silicon germanium layer in the one or more recesses and extending over an apex of the one or more faceted silicon oxide caps.

### CROSS-REFERENCE TO RELATED APPLICATIONS

This application claims benefit of U.S. Provisional Patent Application Ser. No. 62/448,563, filed on Jan. 20, 2017, which is herein incorporated by reference in its entirety.

### BACKGROUND

### Field

Aspects of the present disclosure generally relate to semiconductor devices and methods of manufacture thereof. More specifically, semiconductor devices having a thin, low-defect, fully-relaxed silicon germanium layer, and methods of manufacture thereof are described.

### Description of the Related Art

Many semiconductor devices include a strained silicon layer formed over a silicon germanium layer. The manufacturing processes of such devices are problematic due to the lattice mismatch between the two materials. Conventionally, a silicon germanium layer has been deposited over a blank silicon wafer to decrease or reduce the lattice mismatch between the two materials, however, when the silicon germanium is deposited over the blank silicon wafer, the silicon germanium must be of sufficient thickness. These conventional methods generally include epitaxial deposition of the thick silicon germanium layer. Epitaxial deposition is a prolonged process and depositing a sufficiently thick layer of silicon germanium to reduce the lattice mismatch takes a great amount of time, which results in an overall decreased silicon throughput. Moreover, the conventionally deposited silicon germanium layer exhibits high defect density.

Thus, there is a need in the art for semiconductor devices having silicon formed over a thin, low-defect, relaxed silicon germanium layer and methods of manufacture thereof.

### SUMMARY

The present disclosure generally relates to a device having a thin, low-defect, fully-relaxed silicon germanium (SiGe) layer, and methods of manufacture thereof. The methods generally include depositing a silicon oxide layer on a silicon layer, patterning the silicon oxide layer, exposing the silicon oxide layer to an etchant to form one or more recesses in the silicon layer and one or more faceted silicon oxide caps, and epitaxially growing a silicon germanium layer in the one or more recesses and over an apex of the one or more faceted silicon oxide caps. The device generally includes a silicon layer having one or more recesses defining one or more vertical extensions, one or more faceted silicon oxide caps on the one or more vertical extensions, and a silicon germanium layer in the one or more recesses and extending over an apex of the one or more faceted silicon oxide caps.

In one aspect, a method is disclosed. The method includes depositing a silicon oxide layer on a silicon layer, patterning the silicon oxide layer, exposing the silicon oxide layer to an etchant to form one or more recesses in the silicon layer and one or more faceted silicon oxide caps, and epitaxially growing a silicon germanium layer in the one or more recesses, the silicon germanium layer extending over an apex of the one or more faceted silicon oxide caps.

In another aspect, a method is disclosed. The method includes depositing a silicon oxide layer on a silicon layer, patterning the silicon oxide layer, exposing the silicon oxide layer to an etchant to form one or more recesses in the silicon layer and one or more faceted silicon oxide caps, epitaxially growing a silicon germanium layer in the one or more recesses, the silicon germanium layer extending over an apex of the one or more faceted silicon oxide caps, planarizing the silicon germanium layer, and forming one or more fin structures on the silicon germanium layer.

In yet another aspect, a device is disclosed. The device includes a silicon layer having one or more recesses defining one or more vertical extensions, one or more faceted silicon oxide caps on the one or more vertical extensions, and a silicon germanium layer in the one or more recesses, the silicon germanium layer extending over an apex of the one or more faceted silicon oxide caps.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope, may admit to other equally effective aspects.

FIG. 1 is a flow chart of a method for fabricating a device according to one aspect described herein.

FIGS. 2A-2F depict schematic sectional side views of stages of fabrication of a device in accordance with the method of FIG. 1.

To facilitate understanding, identical reference numerals have been used, where possible, to designate identical elements that are common to the figures. It is contemplated that elements and features of one aspect may be beneficially incorporated in other aspects without further recitation.

### DETAILED DESCRIPTION

The present disclosure generally relates to a device having a thin, low-defect, fully-relaxed silicon germanium (SiGe) layer, and methods of manufacture thereof. The methods generally include depositing a silicon oxide layer on a silicon layer, patterning the silicon oxide layer, exposing the silicon oxide layer to an etchant to form one or more recesses in the silicon layer and one or more faceted silicon oxide caps, and epitaxially growing a silicon germanium layer in the one or more recesses and over an apex of the one or more faceted silicon oxide caps. The device generally includes a silicon layer having one or more recesses defining one or more vertical extensions, one or more faceted silicon oxide caps on the one or more vertical extensions, and a silicon germanium layer in the one or more recesses and extending over an apex of the one or more faceted silicon oxide caps.

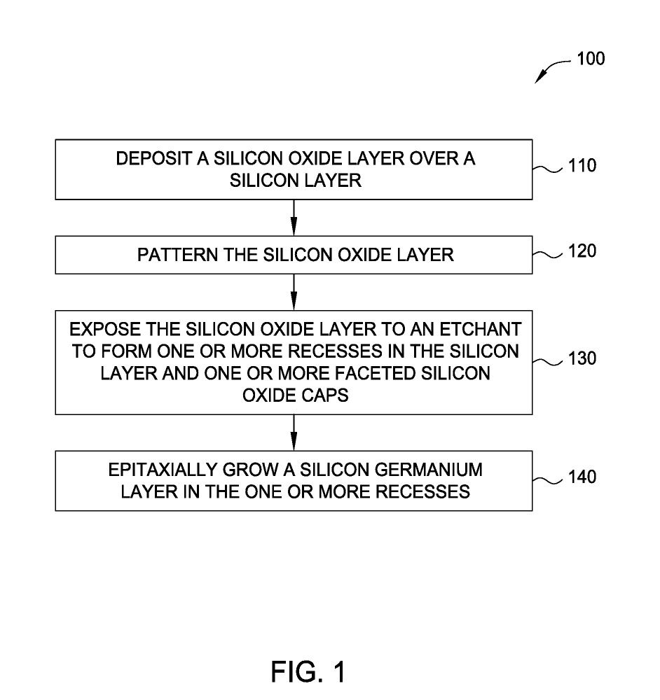

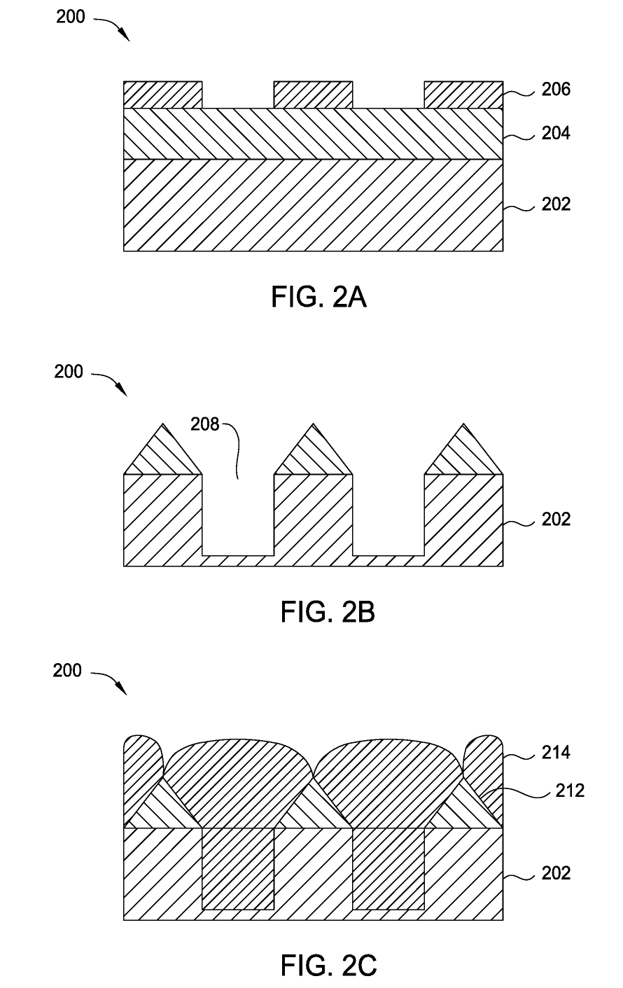

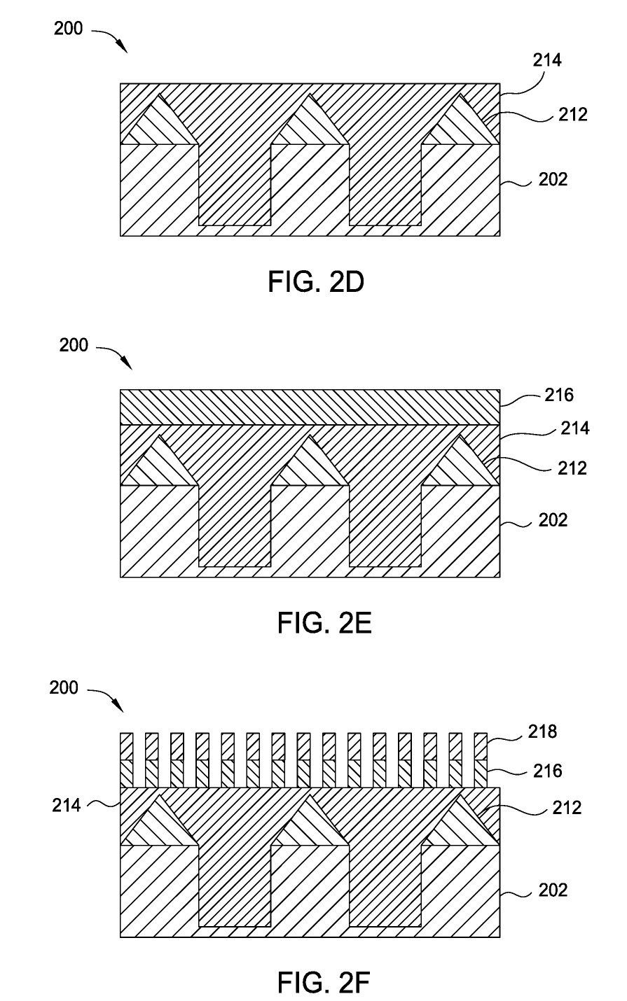

FIG. 1 is a flow chart of a method 100 for fabricating a device according to one aspect described herein. FIGS. 2A-2F depict schematic sectional side views of stages of fabrication of a device 200 in accordance with the method 100 of FIG. 1.

The method 100 begins at operation 110 by depositing a silicon oxide layer 204 on a silicon layer 202 (or silicon substrate), as shown in FIG. 2A. The silicon oxide layer 204 is generally deposited by blanket chemical vapor deposition (CVD) or any other suitable deposition process. In one example, the silicon oxide layer 204 is deposited on and in contact with the silicon layer 202. The silicon layer 202 generally has a thickness of between about 40 nanometers (nm) and about 80 nm. In one example, the silicon oxide layer 204 comprises silicon dioxide (SiO₂). In another example, the silicon oxide layer 204 comprises silicon monoxide (SiO). The silicon oxide layer 204 generally has a thickness of between about 20 nm and about 40 nm.

At operation 120 in method 100 of FIG. 1, the silicon oxide layer 204 is patterned. As shown in FIG. 2A, the silicon oxide layer 204 is patterned using a mask 206. The mask 206 covers at least a portion of the silicon oxide layer 204. In FIG. 2A, the mask covers more than one half of the surface of the silicon oxide layer 204. The mask 206 is generally a photoresist material and may be deposited on an in contact with the silicon oxide layer 204. In alternative examples, the silicon oxide layer 204 may be patterned using lithography or any other suitable patterning process. The patterning produces a template for growth of fully-relaxed silicon germanium.

At operation 130 in method 100 of FIG. 1, the silicon oxide layer 204 is exposed to an etchant to form one or more recesses 208, defined by vertical extensions of the silicon layer 202, and one or more faceted silicon oxide caps 212, as shown in FIG. 2A. The etchant generally includes at least one low-selectivity etchant suitable for dry, low selective oxide etch processes using an inductively coupled plasma (ICP) detector. The low selectivity etchant gradually reduces the mask 206 such that the one or more faceted silicon oxide caps 212 are formed on the vertical extensions of the silicon layer 202. The one or more faceted silicon oxide caps 212 may be formed on and in contact with the vertical extensions of the silicon layer 202. In one example, each of the one or more recesses 208 has a depth of between about 20 nm and about 50 nm, and each of the one or more faceted silicon oxide caps 212 has at least one side having an angle of between about 50 degrees and about 60 degrees, for example 54.7 degrees. When the sloped angle is 57 degrees, the sloped angle of each of the one or more faceted silicon oxide caps 212 is the same as the silicon or silicon germanium facets. The sloped angle of each of the one or more faceted silicon oxide caps may be further tuned by applying a higher bias to the device 200.

After the silicon oxide layer 204 and the silicon layer 202 have been exposed to the etchant to form the one or more recesses 208 and one or more faceted silicon oxide caps 212, the device 200 may be cleaned with an oxygen-based plasma, for example, O₂. The one or more recesses 208 may then be exposed to cleaning plasma, including but not limited to, at least one of ammonia (NH₃) and nitrogen trifluoride (NF₃), to remove any native oxides formed on the sidewalls or bottoms of the one or more trenches.

At operation 140, a silicon germanium layer 214 is epitaxially grown in the one or more recesses 208, as shown in FIG. 2C. More specifically, the device 200 may be transferred into an epitaxial chamber, where the silicon germanium layer 214 is deposited in the one or more recesses 208 by epitaxial deposition. The silicon germanium layer 214 is grown in the one or more recesses and extends over the apexes of the one or more faceted silicon oxide caps 212. The epitaxial deposition process is generally a high-selective epitaxy process such that there is no silicon germanium growth on any dielectric material within the device 200.

In one example, the selectivity of the epitaxial deposition of the silicon germanium layer 214 may be adjusted using increased temperature control. In another example, the selectivity of the epitaxial deposition of the silicon germanium layer 214 may be adjusted by exposing the device to a chlorine gas, for example, hydrogen chloride (HCl). The silicon germanium layer 214 inside the one or more recesses 208 is strained because of the lattice mismatch between the silicon layer 202 and the silicon germanium layer 214. However, the silicon germanium layer 214 outside of the one or more recesses 208 and extending over the apexes of the one more faceted silicon oxide caps 212 is relaxed. More specifically, the silicon germanium layer 214 becomes more relaxed as it is grown upwards through the one or more recesses 208 and over the apexes of the one or more faceted silicon oxide caps 212 such that the uppermost portion, or the surface portion, is fully relaxed silicon germanium. The term “fully relaxed” generally means that the lattice constant of the silicon germanium matches the lattice constant of the bulk substrate material. The silicon germanium layer 214 generally has a thickness less than about 100 nm.

After operation 140, the silicon germanium layer 214 is optionally planarized, as shown in FIG. 2D. The optional planarization may be performed by chemical mechanical planarization (CMP). After planarization, a wet clean process may be used and then a second amount of silicon germanium 216 may be epitaxially deposited on the planarized silicon germanium layer 214, as shown in FIG. 2E. The second amount of silicon germanium 216 may be deposited on and in contact with the silicon germanium layer 214. The planarization and epitaxially deposition of the second amount of silicon germanium 216 are optional such that the following operations may be performed after operation 140 without the planarization and/or epitaxial deposition of the second amount of silicon germanium 216. The planarization and epitaxial deposition of the second amount of silicon germanium may further reduce the defects of the silicon germanium layer 214.

Next, one or more fin structures 218 are formed on the silicon germanium layer 214 or the second amount of silicon germanium 216, as shown in FIG. 2F. More specifically, an additional silicon layer is deposited on the silicon germanium layer 214 or the second amount of silicon germanium 216. The additional silicon layer may be deposited on an in contact with the silicon germanium layer 214 or the second amount of silicon germanium 216. The additional silicon layer and the silicon germanium layer 214 and/or the second amount of silicon germanium 216 are patterned. In one example, the patterning is a double patterning. In another example, the patterning is a quadruple patterning. The patterning may be similar to the patterning described at operation 120 of the method 100. In one example, the patterning may be performed by positioning a mask over at least a portion of the additional silicon layer to form the one or more fin structures 218. In another example, the patterning may be performed by performing any suitable lithography on the one or more fin structures 218 and silicon germanium layer 214 and/or second amount of silicon germanium 216. Then, the additional silicon layer and the silicon germanium layer 214 and/or the second amount of silicon germanium layer 214 are exposed to a second etchant to form one or more trenches through the additional silicon layer and the silicon germanium layer 214 to form the one or more fin structures 218.

The one or more fin structures 218 generally include strained silicon. The one or more fin structures 218 including strained silicon generally exhibit increased electrical performance than relaxed silicon. More particularly, the one or more fin structures 218 including strained silicon generally exhibit increased electron mobility. In another example, the one or more fin structures 218 may be formed inside the one or more recesses 208. While the foregoing contemplates formation of one or more fin structures 218 including strained silicon, a germanium layer may be deposited over the silicon germanium layer 214 or the second amount of silicon germanium 216 and then patterned and exposed to etchant to form a one or more germanium fin structures.

Benefits of the described aspects include fabrication of devices having low-defect, strained silicon or germanium fin structures over a thin, fully-relaxed silicon germanium layer and silicon substrate. The thinness of the silicon germanium layer reduces overall semiconductor device manufacturing time. Moreover, the silicon germanium layer becomes fully relaxed at the uppermost surface and exhibits low defects. Overall, the described methods produce semiconductor devices having improved electron mobility.

While the foregoing aspects contemplate growth of strained silicon fins or germanium fins on a silicon substrate, the methods and devices described herein may also be used to grow low-defect Group III-V films on semiconductor devices.

While the foregoing is directed to aspects of the present disclosure, other and further aspects of the disclosure may be devised without departing from the basic scope thereof, and the scope thereof is determined by the claims that follow.

1. A method, comprising:
depositing a silicon oxide layer on a silicon layer;
patterning the silicon oxide layer;
exposing the silicon oxide layer to an etchant to form one or more recesses in the silicon layer and one or more faceted silicon oxide caps; and
epitaxially growing a silicon germanium layer in the one or more recesses, the silicon germanium layer extending over an apex of the one or more faceted silicon oxide caps.

2. The method of claim 1, wherein the patterning the silicon layer comprises positioning a mask on at least a portion of the silicon oxide layer.

3. The method of claim 1, wherein the patterning the silicon layer comprises performing lithography on the silicon oxide layer.

4. The method of claim 1, further comprising planarizing the silicon germanium layer.

5. The method of claim 4, further comprising forming one or more fin structures on the silicon germanium layer.

6. The method of claim 5, wherein the forming one or more fin structures on the silicon germanium layer comprises:
depositing an additional silicon layer on the silicon germanium layer;
patterning the additional silicon layer and the silicon germanium layer; and
exposing the additional silicon layer and the silicon germanium layer to a second etchant to form one or more trenches through the additional silicon layer and the silicon germanium layer.

7. The method of claim 4, further comprising depositing an additional silicon germanium layer on the silicon germanium layer.

8. The method of claim 1, wherein the silicon germanium layer in the one or more recesses is strained, and wherein the silicon germanium layer extending over the apex of the one or more faceted silicon oxide caps is relaxed.

9. A method, comprising:
depositing a silicon oxide layer on a silicon layer;
patterning the silicon oxide layer;
exposing the silicon oxide layer to an etchant to form one or more recesses in the silicon layer and one or more faceted silicon oxide caps;
epitaxially growing a silicon germanium layer in the one or more recesses, the silicon germanium layer extending over an apex of the one or more faceted silicon oxide caps;
planarizing the silicon germanium layer; and
forming one or more fin structures on the silicon germanium layer.

10. The method of claim 9, wherein the patterning the silicon layer comprises positioning a mask on at least a portion of the silicon oxide layer.

11. The method of claim 9, further comprising exposing the one or more recesses to cleaning plasma, wherein the cleaning plasma comprises at least one of NH₃ and NF₃.

12. The method of claim 9, wherein forming one or more fin structures on the silicon germanium layer comprises:
depositing an additional silicon layer on the silicon germanium layer;
patterning the additional silicon layer and the silicon germanium layer; and
exposing the additional silicon layer and the silicon germanium layer to a second etchant to form one or more trenches through the additional silicon layer and the silicon germanium layer.

13. The method of claim 11, wherein the patterning the additional silicon layer and the silicon germanium layer comprises positioning a mask on at least a portion of the additional silicon layer.

14. A device, comprising:
a silicon layer having one or more recesses defining one or more vertical extensions;
one or more faceted silicon oxide caps on the one or more vertical extensions; and
a silicon germanium layer in the one or more recesses, the silicon germanium layer extending on an apex of the one or more faceted silicon oxide caps.

15. The device of claim 14, wherein the silicon germanium layer in the one or more recesses is strained, and wherein the silicon germanium layer extending over the apex of the one or more faceted silicon oxide caps is relaxed.

16. The device of claim 14, wherein an angle of a side of the one or more faceted silicon oxide caps is between about 50 degrees and about 60 degrees.

17. The device of claim 14, wherein the silicon germanium layer has a thickness of less than 100 nanometers.

18. The device of claim 14, further comprising a plurality of fin structures on the silicon germanium layer.

19. The device of claim 18, wherein the plurality of fin structures are deposited on and in contact with the relaxed silicon germanium layer.

20. The device of claim 18, wherein the plurality of fin structures comprises strained silicon.
